(19) United States
(12) Patent Application Publication
(10) Pub. No.: US 2005/0190542 A1
(43) Pub. Date: Sep. 1, 2005

(54) Case for handheld device

(76) Inventor: Bill Tsang Chun Chee, Kwai Fong (CN)

Correspondence Address: BOHAN, MATHERS & ASSOCIATES, LLC, PO BOX 17707, PORTLAND, ME, 04112-8707, US

(21) Appl. No.: 10/790,585

(22) Filed: Mar. 1, 2004

(51) Int. Cl. H01Q 1/24; H05K 5/06; H05K 5/04; H05K 5/00

(52) U.S. Cl. 361/752

(57) ABSTRACT

A case that securely holds a handheld device and allows for charging the device while it is held in the case. The case includes a two-fold panel that folds on itself to form a cavity for receiving the handheld device. A device bracket for holding the handheld device is attached to a strap that is movably affixed to the inside of the case and holds the handheld device without covering the display and keypad areas. The portions of the case that cover the front and back surfaces of the handheld device fold back, away from the device bracket, thereby freeing up the end of the handheld device with the charging connector so that it may be inserted into a charging station.

### BACKGROUND INFORMATION

1. Field of the Invention

The invention relates to the field of cases for small, handheld devices, such as PDAs, MP3 players and other devices. More particularly, the invention relates to a case that allows the handheld device to be connected to a synchronization or charging station without first removing it from the case.

2. Description of the Prior Art

Handheld devices are ubiquitous today. Typically, such handheld devices have a connector at one end for charging the rechargeable battery in the device. To recharge the device, it is inserted into a docking or charging station. Many types of cases for holding such handheld devices are known. The cases typically enclose all sides of the handheld device. The disadvantage of conventional cases is that the handheld device must first be removed from the case in order to insert it into the charging station.

Cases that include a means of attaching the handheld device to the case without enclosing it on all sides are also known. One type of attachment means is a strap that wraps around the enclosed handheld device securing the device to the case. The strap is typically constructed of a hook-and-loop type fastener. A disadvantage of such a strap is that it may tear loose from the case and allow slippage of the handheld device. Another type of attachment means is a self-adjusting bracket. This bracket includes a spring-biased clip that allows the bracket to expand to receive and then to retract to securely hold the handheld device. The disadvantage of this bracket is that it includes moving parts that may wear out or break and that also increase the cost of manufacturing.

Most handheld electronic devices require docking to a charging station to recharge their batteries and to transfer data to and from the device. It is desirable not to have to remove the handheld device from its case in order to be able to dock the device with the charging station. Motson (U.S. Pat. No. 6,612,432 B2; 2003) discloses a case for portable electronic devices that has a bottom flap that may be opened to allow the device to be connect to the charging station. A disadvantage of this case is that the electronic device is not securely attached to the case and can slide out of the case if the flap is open. Another disadvantage is that the keypad of the handheld device is not exposed, thereby prohibiting the use of the device while it is in the case.

Hazzard et al. (U.S. patent Publication U.S. Ser. No. 2002/0163778 A1; 2002) discloses a case for a PDA that includes a keyboard and pass-through I/O port that enables the PDA to remain in the case while connected to the keyboard. The disadvantage of this case is it includes a keyboard and an I/O port that is only suitable for certain types of PDAs. Another disadvantage of this case is that it does not fully encase the handheld device, thereby exposing the device to damage.

Furthermore, handheld electronic devices often use removable memory cards to expand the useable memory or storage of the devices. Users may have several removable memory cards that perform different functions. For instance, a user may use one removable memory card to store music files and another to store digital images. Users wish, of course, to have the removable memory cards readily available. In order to protect the pin connectors on the removable memory card, it should be stored in a protective case when not engaged in a handheld device. It is desirable to have a case that can securely and safely store one or more removable memory cards for quick and easy retrieval.

What is needed, therefore, is a case that securely holds a handheld device even when the case is open. What is further needed is such a case that allows operation of the handheld device while encased. What is yet further needed is such a case that allows the handheld device to connect to a charging station without removing it from the case. What is still yet further needed is such a case that safely and securely stores removable memory cards for easy retrieval.

### BRIEF SUMMARY OF THE INVENTION

For the reasons cited above, it is an object of the present invention to provide a device case that securely holds a handheld device even when the device case is open. It is a further object to provide such a case that allows operation of the handheld device while it is encased. It is a yet further object to provide such a device case that allows the encased handheld device to connect to a charging station without first being removed from the device case. It is a still yet further object to provide such a device case that safely and securely stores removable memory cards for easy retrieval.

The objects of the invention are achieved by providing a case that securely encases the handheld device, yet leaves exposed a docking or charging connector or plug on a charging end of the handheld device when the device case is open. The device case according to the invention comprises a case panel that protects the front and back faces of an encased handheld device. The case panel is a simple two-fold billfold-type panel that folds over on itself to create a cavity in which to receive the handheld device. A rigid device bracket for securely holding the handheld device is attached to the case panel. The device bracket has a pair of flanges that create a groove into which the handheld device is slidable. The device case is sized for a particular handheld device, so that the handheld device forms an interference or friction fit with the device bracket. The portions of the case panel that cover the front and the back faces of the handheld device may be folded back away from the device bracket, thereby freeing the charging plug from any encumbrances. The handheld device is now dockable at a charging station, without first having to remove it from the device case. The device case closes similar to a billfold, that is, it folds over the handheld device, lengthwise, and is secured closed by some fastening means, such as a hook-and-loop type strap, a snap closure, or some other type of fastening means.

The device case according to the invention also provides a removable memory cardholder on the inside of the case panel, providing a convenient space to store one or more conventional removable memory cards. The user simply slides the removable memory card face up into the cardholder. Not only does the removable memory cardholder provide a readily accessible storage place, it also serves to protect the pin connectors.

The device case according to the invention is suitable for use with many different types of handheld electronic devices such as PDAs, MP3 players and cell phones, i.e., any handheld electronic device.

### BRIEF DESCRIPTION OF THE DRAWINGS

The present invention is described with reference to the accompanying drawings. In the drawings, like reference numbers indicate identical or functionally similar elements. Additionally, the left-most digit(s) of a reference number identifies the drawing in which the reference number first appears.

FIG. 1 is a side view of the device case with a device bracket according to the invention.

FIG. 2 is a side view of the device case of FIG. 1, showing the device case with the case panel sides folded back exposing a handheld device held by the device bracket.

FIG. 3 is a top view of the device case of FIG. 2.

FIG. 4 is a top view of the device case without a handheld device with the case panel sides folded back.

FIG. 5 is a cross-sectional view of the PC cardholder embedded in the case panel.

### DETAILED DESCRIPTION OF THE INVENTION

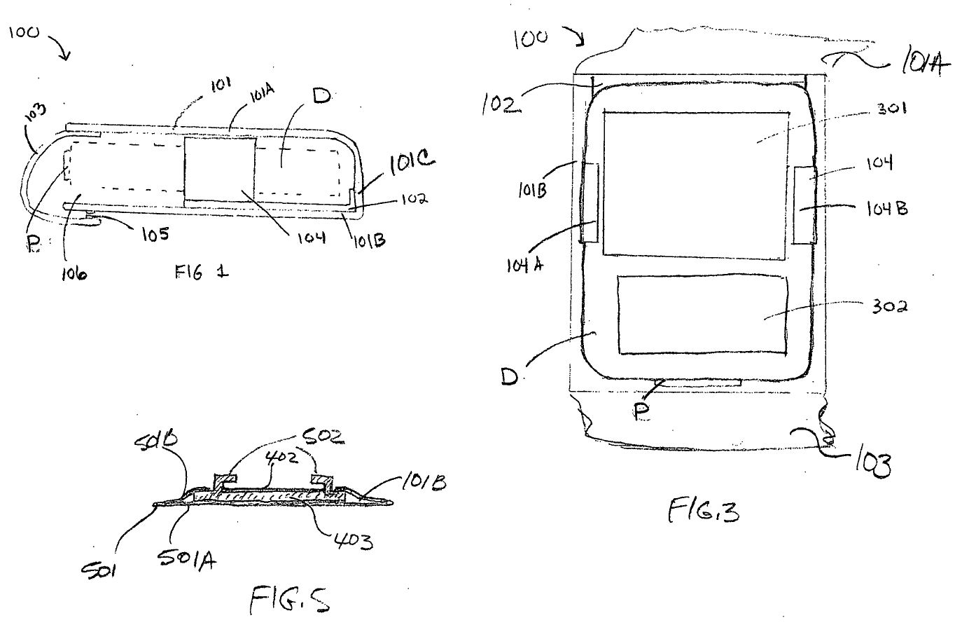

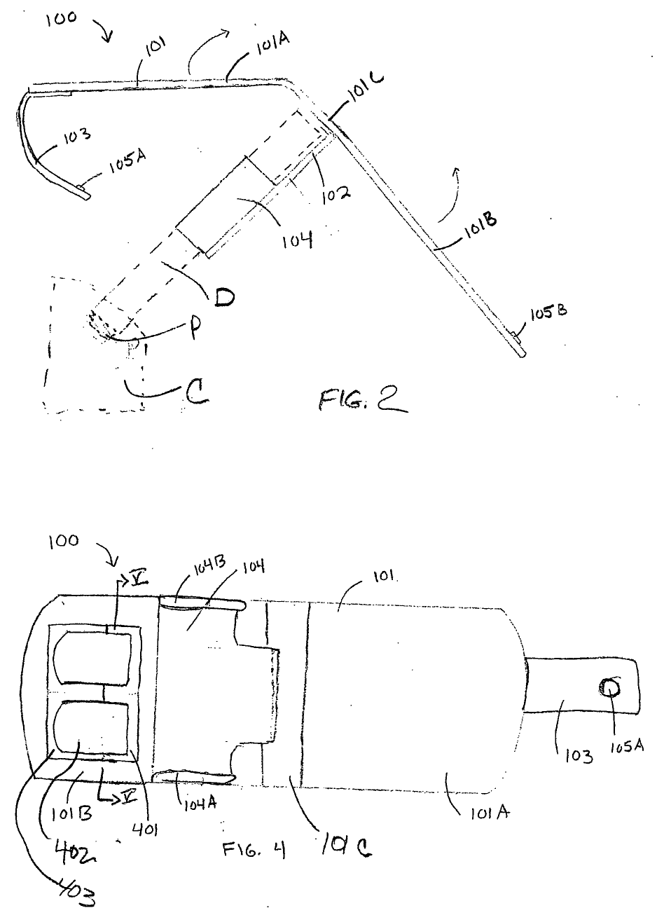

FIGS. 1 and 2 show a side view of a device case 100 according to the invention in a closed and an open state, respectively. The device case 100 comprises an open-sided case panel 101, having a device bracket 104 and a closure strap 103. The case panel 101 is a substantially flat bendable or foldable body having a first panel 101A, a second panel 101B and an intermediate panel 101C. The case panel 101 folds closed forming a cavity 106 that provides space for a handheld device D. The closure strap 103 is fixedly attached to the first panel 101A and is provided with a closure means 105 that secures the first panel 101A to the second panel 101B. The device bracket 104 is attached to the intermediate panel 101C. In the embodiment shown, the device bracket 104 is integrated with a device bracket strap 102 that is pivotably attached at one end to the intermediate panel 101C, with the device bracket 104 at the other end. The device bracket 104 is shaped to receive and securely hold the handheld device D, which is shown in dashed lines. The typical handheld device D includes a charging connector or plug P that is used to connect the handheld device D to a charging or synchronization station C, as shown in FIG. 2.

FIG. 2 illustrates the use of the device case 100 with a handheld device D. The handheld device D, shown in dotted lines, is inserted into the device bracket 104, with the device bracket strap 102 extending from the intermediate panel 101 C, with the first panel 101A and the second panel 101B folded away from the handheld device D, thereby exposing the charging plug P and allowing it to be connected to the charging or synchronization station C.

FIG. 3 is a top view of the device case 100 of FIG. 1, showing the case panel 101 in the open position, with the handheld device D inserted into the device bracket 104. The device bracket 104 is a simple bracket with two bracket flanges 104A, 104B. The handheld device D is insertable between the flanges 104A, 104B. Preferably, the bracket flanges 104A, 104B provide a tight fit, so as to provide a secure hold on the handheld device D. The bracket flanges 104A, 104B are narrow, so as not to impede a view of or access to a display field 301 and a keypad field 302 of the typical handheld device D. Thus, the handheld device D may be operated while encased in the device case 100.

FIGS. 4 and 5 illustrate a PC cardholder 401. FIG. 4 is a top view of the device case 100 in the open position, showing the device bracket 104 and the removable memory cardholder 401 and FIG. 5 is a cross-sectional view of the removable memory cardholder 401. In the embodiment shown, the removable memory cardholder 401 comprises a base plate 402 and a frame 403. The frame 403 is embedded in the second panel 101B of the case panel 101 and has narrow flanges 502 that form grooves into which the conventional removable memory card is insertable. The base plate 402 is made of a smooth, flat, and rigid piece of material that will maintain the removable memory cards in a flat position and protect the connector pins from dust, lint, and other contaminants. It should be pointed out that the frame 403 and base plate 402 may be constructed of an integral piece of rigid plastic. In this case, the removable memory cardholder 401 does not need to have a separate base plate 402 because the frame 403 alone then provides the necessary rigidity to protect the removable memory cards. The removable memory cardholder 401 as shown is capable of holding two conventional removable memory cards although, depending on the size of the device case 100, the removable memory cardholder 401 may provide for one or more removable memory cards.

In the embodiment shown, the case panel 101 is manufactured in a leather, leather-like, or synthetic material that is durable and looks fashionable. If made with this type of material, the case panel 101 is a flexible skin 501, comprising an outer skin 501A and an inner skin 501B that are stitched or glued together. A padding may be inserted between the outer and inner skins 501A, 501B to provide greater stiffness to all or portions of the case panel 101 or to add a thickness and improve tactile appeal. The case panel 101 according to the invention is, however, not limited to a construction of leather or leather-like material. Rather, it is within the scope of the invention to provide the case panel 101 made of other materials, such as, but not limited to, a molded plastic case, or a case made of a metallic material, having a hinge at the junctions between the intermediate section 101C and the first panel 10A, and between the intermediate section 101C and the second panel 101B.

The device bracket 104 is preferably manufactured of a sturdy material such as a rigid, non-brittle plastic or a piece of formed sheet metal, although any material having the desired rigidity and elasticity to securely hold the handheld device D may be used. The device bracket 104 in the preferred embodiment is made of metal and, for reasons of aesthetics, is enclosed with the same material used to form the flexible skin 501 for the case panel. The material is extended beyond the end of the device bracket 104 to form the bracket strap 102, that is then stitched, adhesively attached, or otherwise fastened to the case panel 101. Using the material for the flexible skin 501 serves a dual purpose: it is flexible and, therefore, can move relative to the first and second panels 101A, 101, which makes it easier to free the plug end from an encumbering encasing and to maneuver the handheld device D into the charging or synchronization station C.

The closure strap 103 may be constructed of the same leather or leather-like material used for the case panel 101, or of other suitable material. The scope of the invention encompasses any number of types of closure straps, such as woven straps, straps made of hook-and-loop material, such as VELCRO@, or elastic straps that stretch around the case panel 101. Other closure means may be considered, such as a zipper, a snap, or other types of clasps.

It is understood that the embodiments described herein are merely illustrative of the present invention. Variations in the construction of the device case may be contemplated by one skilled in the art without limiting the intended scope of the invention herein disclosed and as defined by the following claims.

1. A case for a handheld device having a connector for charging said handheld device, said case comprising:
a case panel, said case panel having a first panel and a second panel, and an intermediate panel therebetween, wherein said case panel is foldable so as to form an open-sided enclosure for receiving said handheld device;
a device bracket having a first end for receiving said handheld device and a second end that is attached to a bracket strap that is movably attached to said case panel; and
a closure means attached to said first panel and said second panel.

2. The case of claim 1 further comprising a removable cardholder that is affixed to said case panel.

3. The case of claim 2, wherein said case panel has an inner side and wherein said removable memory cardholder is affixed to said inner side.

4. The case of claim 3, wherein said removable memory cardholder includes a frame for slidably holding a removable memory card.

5. The case of claim 4, wherein said frame includes two removable memory card slots for holding two removable memory cards.
